(19) United States
(12) Patent Application Publication
(10) Pub. No.: US 2011/0317112 A1
(43) Pub. Date: Dec. 29, 2011

(54) LIQUID CRYSTAL DISPLAY DEVICE AND METHOD FOR PRODUCING THE SAME

(76) Inventors: Yasushi Asaoka, Osaka (JP); Kiyoshi Minoura, Osaka (JP); Eiji Satoh, Osaka (JP); Kazuhiro Deguchi, Osaka (JP); Sayuri Fujiwara, Osaka (JP); Kenji Miyamoto, Osaka (JP)

(21) Appl. No.: 13/148,368

(22) PCT Filed: Feb. 15, 2010
(86) PCT No.: PCT/JP2010/000919

§ 371 Date: Aug. 8, 2011

(30) Foreign Application Priority Data
May 28, 2009 (JP) 2009-128673

(51) Int. Cl. G02F 1/1335; H05K 13/00

(52) U.S. Cl. 349/113; 349/122; 29/592.1

(57) ABSTRACT

An ultraviolet-absorbing layer is provided between an insulating substrate and a transparent electrode, the ultraviolet-absorbing layer having a transmittance ratio (T (365 nm)/T (315 nm)) of not less than 6.3 where (T (365 nm)) is a transmittance at a wavelength of 365 nm and (T (315 nm)) is a transmittance at a wavelength of 315 nm.

### TECHNICAL FIELD

The present invention relates to a liquid crystal display device and a method for producing the liquid crystal display device.

### BACKGROUND ART

Recently, reflective display devices using light of ambient environments are highly expected especially as display devices of mobile phones, electronic books, and the like. This is because the reflective display devices do not need a backlight and they have such advantages that they are reduced in power consumption, thickness, and weight.

Among these reflective display devices, reflective LCD devices are being widely used. Some of the reflective LCD devices employ a method in which an excellent black display is attained by use of a polarizing plate and a liquid crystal layer that controls a polarization state of light passing therethrough. Further, some of the reflective LCD devices employ a method in which an excellent white display is attained by use of a liquid crystal layer that controls a scattering state of light passing therethrough, without using any polarizing plates.

As the method that does not use a polarizing plate, the following methods are well known: (i) a Dynamic Scattering Mode (DSM) method that uses scattering caused by a convective flow of liquid crystal molecules; (ii) a Polymer Dispersed Liquid Crystal (PDLC) method in which a scattering state is formed by a structure in which liquid crystal drops are dispersed in a polymer film; and (iii) a Polymer Network Liquid Crystal (PNLC) method in which a scattering state is formed by a structure in which a polymer network is formed in a liquid crystal layer.

Further, for the purpose of using the reflective LCD devices in mobile devices, how much power consumption can be reduced is a major concern. In view of this, there is such an attempt to achieve ultra-low power consumption that a liquid crystal display device is so arranged that a plurality of active elements are provided in each pixel so as to incorporate a static RAM therein and the liquid crystal display device is driven at an alternating voltage with a low frequency of about 1 Hz.

However, it is known that liquid crystal materials are degraded by ultraviolet radiation, and ionic impurities caused by the degradation deteriorate properties of the liquid crystal materials. Especially, it is well known that liquid crystals used in the PDLC method and the PNLC method are easily affected by ultraviolet light. Moreover, when a liquid crystal display device is driven at a frequency of 1 Hz, a voltage having the same polarity is applied thereto longer than when the liquid crystal display device is driven at a frequency of 60 Hz, which is a conventional frequency. This causes the ionic impurities to easily move and results in easy accumulation of the ionic impurities at an interface between liquid crystals and an alignment film. As a result, an effective voltage applied to the liquid crystal layer is reduced, thereby causing flickers. In view of this, for the PDLC method and the PNLC method in which a static RAM is incorporated, it is especially necessary to restrain degradation of the liquid crystals by ultraviolet radiation.

Patent Literature 1 discloses a technique for restraining such degradation of the liquid crystal materials due to ultraviolet radiation.

### CITATION LIST

### Patent Literature 1

Japanese Patent Application Publication, Tokukaihei, No. 06-294957 A (1994)

### SUMMARY OF INVENTION

### Technical Problem

Generally, ultraviolet indicates light having a wavelength of not more than 380 nm, which is shorter than that of visible light. However, the PDLC method and the PNLC method require ultraviolet having a wavelength of 365 nm, which is strong enough to cause polymerization. For the PDLC method and the PNLC method, it is necessary to effectively block ultraviolet having a wavelength of not more than 340 nm, which causes deterioration of liquid crystals. In particular, ultraviolet having a wavelength of 315 nm and ultraviolet having a wavelength of 335 nm, which are emitted from a fluorescent lamp, are large factors to cause the deterioration. Therefore, it is necessary to block those kinds of ultraviolet. However, the technique disclosed in Patent Literature 1 evenly blocks every kind of ultraviolet. That is, in Patent Literature 1, ultraviolet necessary for a production process is not distinguished from ultraviolet necessary to be blocked because it causes the deterioration of liquid crystals. When ultraviolet of necessary wavelengths is blocked, polymerization is performed insufficiently, thereby making it unfortunately difficult to obtain an element having excellent properties. Further, if blocking of ultraviolet is insufficient, liquid crystals are exposed to ultraviolet while they are processed or irradiated with ultraviolet from a fluorescent lamp while they are carried. This renders the liquid crystals deteriorated.

An object of the present invention is to provide (i) a liquid crystal display device that uses an ultraviolet-absorbing layer optimum for the PDLC method and PNLC method, and (ii) a method for producing the liquid crystal display device.

### Solution to Problem

A liquid crystal display device of the present invention, including: substrates wherein electrodes formed on one of the substrates are paired with electrodes formed on the other one of the substrates; a liquid crystal sandwiched between the substrates, the liquid crystal being arranged by dispersing liquid crystal drops in a polymer film or by forming a polymer network in a liquid crystal layer; and an ultraviolet-absorbing layer provided between at least one of the substrates and the pair of electrodes, the ultraviolet-absorbing layer having a transmittance ratio (T (365 nm)/T (315 nm)) of not less than 6.3 where a transmittance at a wavelength of 365 nm is (T (365 nm)) and a transmittance at a wavelength of 315 nm is (T (315 nm)).

According to the above arrangement, it is possible to sufficiently polymerize a polymer and fully prevent deterioration in the liquid crystal due to ultraviolet. This makes it possible to attain a liquid crystal display device having an excellent display quality.

A reflective liquid crystal display device of the present invention, including: a first insulating substrate on which (i) a memory including a plurality of active elements, (ii) an interlayer insulating film and (iii) a reflective electrode are formed in this order; a second insulating substrate on which a transparent electrode is formed, the first insulating substrate and the second insulating substrate being attached to each other such that the reflective electrode formed on the first insulating substrate faces the transparent electrode formed on the second insulating substrate; a liquid crystal sandwiched between the first insulating substrate and the second insulating substrate, the liquid crystal being arranged by dispersing liquid crystal drops in a polymer film or by forming a polymer network in a liquid crystal layer; and an ultraviolet-absorbing layer provided between the second insulating substrate and the transparent electrode, the ultraviolet-absorbing layer having a transmittance ratio (T (365 nm)/T (315 nm)) of not less than 6.3 where (T (365 nm)) is a transmittance at a wavelength of 365 nm and T (315 nm) is a transmittance at a wavelength of 315 nm.

The ultraviolet-absorbing layer has a thickness of 1.0 μm to 3.0 μm.

According to such an arrangement that includes the ultraviolet-absorbing layer, it is possible to sufficiently polymerize a polymer and fully prevent deterioration in the liquid crystal due to ultraviolet. This makes it possible to attain a reflective liquid crystal display device having an excellent display quality.

A method for producing a reflective liquid crystal display device of the present invention including the steps of preparing a first insulating substrate on which (i) a memory including a plurality of active elements, (ii) an interlayer insulating film and (iii) a reflective electrode are formed in this order; preparing a second insulating substrate on which an ultraviolet-absorbing layer and a transparent electrode are formed in this order, the ultraviolet-absorbing layer having a transmittance ratio (T (365 nm)/T (315 nm)) of not less than 6.3 where (T (365 nm)) is a transmittance at a wavelength of 365 nm and (T (315 nm)) is a transmittance at a wavelength of 315 nm; attaching the first insulating substrate and the second substrate to each other such that the reflective electrode formed on the first insulating substrate faces the transparent electrode formed on the second insulating substrate; providing a liquid crystal, a monomer and a photopolymerization initiator between the first insulating substrate and the second insulating substrate; and polymerizing the monomer by irradiating the reflective liquid crystal display device from the second insulating substrate with ultraviolet, the ultraviolet having an intensity of not less than 30 mW/cm² at a wavelength of 365 nm at a liquid crystal panel surface.

It is preferable that the ultraviolet has an intensity ratio (I (365 nm)/I (340 nm)) of not less than 41 where (I (365 nm)) is an intensity at a wavelength of 365 nm and (I (340 nm)) is an intensity at a wavelength of 340 nm.

According to the method according to the present invention, it is possible to sufficiently polymerize a polymer and fully prevent deterioration in the liquid crystal due to ultraviolet. This makes it possible to attain a reflective liquid crystal display device having an excellent display quality.

### Advantageous Effects of Invention

A liquid crystal display device of the present invention is a reflective liquid crystal display device including: substrates wherein electrodes formed on one of the substrates are paired with electrodes formed on the other one of the substrates; a liquid crystal sandwiched between the substrates, the liquid crystal being arranged by dispersing liquid crystal drops in a polymer film or by forming a polymer network in a liquid crystal layer; and an ultraviolet-absorbing layer provided between at least one of the substrates and the pair of electrodes, the ultraviolet-absorbing layer having a transmittance ratio (T (365 nm)/T (315 nm)) of not less than 6.3 where a transmittance at a wavelength of 365 nm is (T (365 nm)) and a transmittance at a wavelength of 315 nm is (T (315 nm)).

With the above arrangement, ultraviolet having a wavelength of 365 nm necessary for polymerization is hardly absorbed by the ultraviolet-absorbing layer, thereby sufficiently promoting a polymerization reaction for preparing a polymer. As a result, it is possible to sufficiently restrain that the liquid crystal is deteriorated by ultraviolet, thereby resulting in that a liquid crystal display device having a high display quality can be produced.

A reflective liquid crystal display device of the present invention, including: a first insulating substrate on which (i) a memory including a plurality of active elements, (ii) an interlayer insulating film and (iii) a reflective electrode are formed in this order; a second insulating substrate on which a transparent electrode is formed, the first insulating substrate and the second insulating substrate being attached to each other such that the reflective electrode formed on the first insulating substrate faces the transparent electrode formed on the second insulating substrate; a liquid crystal sandwiched between the first insulating substrate and the second insulating substrate, the liquid crystal being arranged by dispersing liquid crystal drops in a polymer film or by forming a polymer network in a liquid crystal layer; and an ultraviolet-absorbing layer provided between the second insulating substrate and the transparent electrode, the ultraviolet-absorbing layer having a transmittance ratio (T (365 nm)/T (315 nm)) of not less than 6.3 where (T (365 nm)) is a transmittance at a wavelength of 365 nm and T (315 nm) is a transmittance at a wavelength of 315 nm.

With the above arrangement, ultraviolet having a wavelength of 365 nm necessary for polymerization for preparing a polymer is hardly absorbed by the ultraviolet-absorbing layer, thereby sufficiently promoting the polymerization. On the other hand, ultraviolet having a wavelength of 315 nm is sufficiently blocked, thereby making it possible to restrain that a liquid crystal material is deteriorated by the ultraviolet having a wavelength of 315 nm which is emitted from a fluorescent lamp or an exposure device used in a production process and which cannot be removed by an ultraviolet cut filter. This arrangement can restrain a reduction in reflectance, thereby making it possible to produce a reflective liquid crystal display device which can perform high-quality display with high contrast and less flickers.

A method for producing a reflective liquid crystal display device of the present invention including the steps of: preparing a first insulating substrate on which (i) a memory including a plurality of active elements, (ii) an interlayer insulating film and (iii) a reflective electrode are formed in this order; preparing a second insulating substrate on which an ultraviolet-absorbing layer and a transparent electrode are formed in this order, the ultraviolet-absorbing layer having a transmittance ratio (T (365 nm)/T (315 nm)) of not less than 6.3 where (T (365 nm)) is a transmittance at a wavelength of 365 nm and (T (315 nm)) is a transmittance at a wavelength of 315 nm; attaching the first insulating substrate and the second substrate to each other such that the reflective electrode formed on the first insulating substrate faces the transparent electrode formed on the second insulating substrate; providing a liquid crystal, a monomer and a photopolymerization initiator between the first insulating substrate and the second insulating substrate; and polymerizing the monomer by irradiating the reflective liquid crystal display device from the second insulating substrate with ultraviolet, the ultraviolet having an intensity of not less than 30 mW/cm² at a wavelength of 365 nm at a liquid crystal panel surface.

According to the above method, ultraviolet having a wavelength of 365 nm necessary to initiate polymerization for preparing a polymer is hardly absorbed by the ultraviolet-absorbing layer, and further, the polymerization is sufficiently promoted because an intensity of irradiation on the liquid crystal panel surface is 30 mW/cm² or more. Further, ultraviolet having a wavelength of 315 nm is sufficiently blocked, thereby making it possible to restrain that a liquid crystal material is deteriorated by the ultraviolet having a wavelength of 315 nm which is emitted from a fluorescent lamp or an exposure device used in a production process and which cannot be removed by an ultraviolet cut filter. This can restrain a reduction in reflectance, thereby making it possible to produce a reflective liquid crystal display device which can perform high-quality display with high contrast and less flickers. Further, in the above method, it is possible to perform, under light emitted from the fluorescent lamp, various processes, such as cutting of a glass after a display element is formed, etching of the glass to reduce the display element in its thickness, and attaching of an optical film to the display element. Accordingly, it is possible to perform these processes more flexibly.

### BRIEF DESCRIPTION OF DRAWINGS

FIG. 1 is a cross-sectional view schematically illustrating an arrangement of a reflective LCD device according to the present invention.

FIG. 2 illustrates a relationship between an intensity of ultraviolet having a wavelength of 365 nm and a reflectance of the reflective LCD device.

FIG. 3 illustrates a relationship between an intensity of ultraviolet having a wavelength of 365 nm and flickers caused during black display.

FIG. 4 is an explanatory view showing how to measure flickers.

FIG. 5 illustrates a circuit configuration used in Examples.

FIG. 6 illustrates a change in reflectance of a case where an ultraviolet-absorbing layer is provided and a change in reflectance of a case where no ultraviolet-absorbing layer is provided.

### DESCRIPTION OF EMBODIMENTS

The following describes in detail a reflective LCD device 100 according to the present invention and a method according to the present invention for producing the reflective LCD device 100, with reference to drawings.

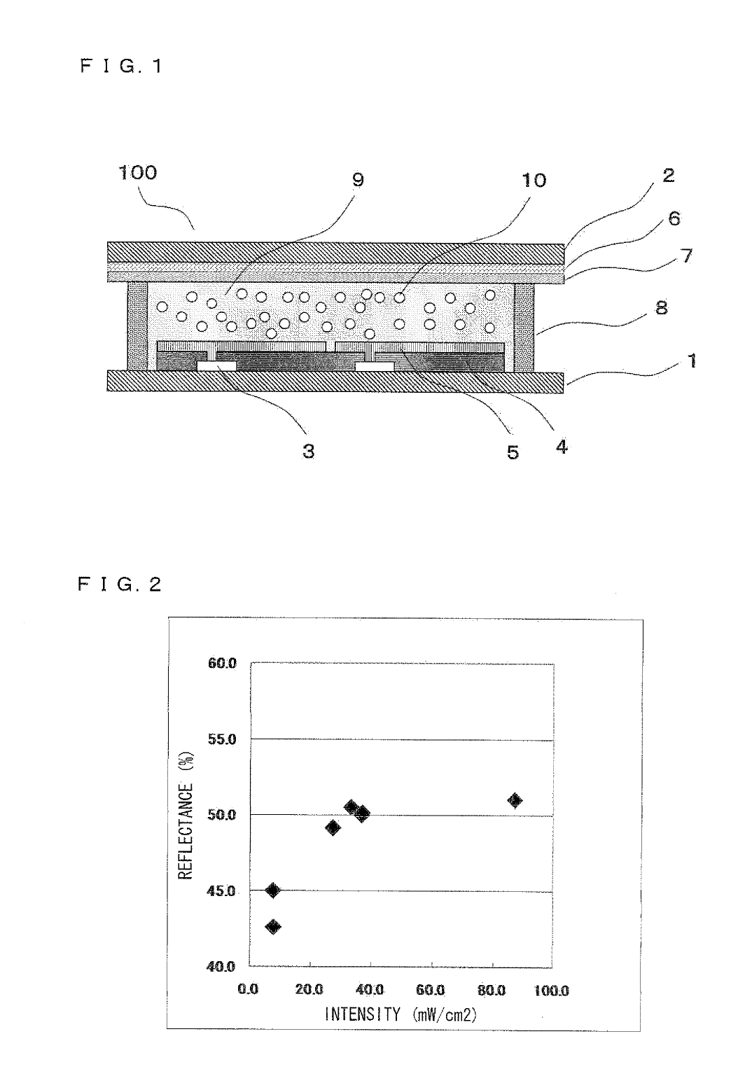

FIG. 1 is a cross-sectional view illustrating the reflective LCD device 100 according to the present invention. The reflective LCD device 100 includes TFT elements (active elements) 3, a first insulating substrate 1 on which an interlayer insulating film 4 and a reflective electrode 5 are provided, a second insulating substrate 2 on which an ultraviolet-absorbing layer 6 and a transparent electrode 7 are provided, and a liquid crystal layer sandwiched between the first insulating substrate 1 and the second insulating substrate 2. The liquid crystal layer is arranged such that liquid crystal drops 10 are dispersed in a polymer film 9. The first insulating substrate is attached to the second insulating substrate via a sealing resin 8. Spacers may be provided in the sealing resin or the liquid crystal layer so as to keep a given distance between these two substrates.

The TFT elements 3 can be formed by a publicly-known method with the use of amorphous silicon, polysilicon, or the like. A source electrode, a drain electrode, and wiring lines to be formed on each of the TFT elements can be also formed by a publicly-known material such as titanium (Ti), molybdenum (Mo) or aluminum (Al). The interlayer insulating film 4 is preferably made from an organic resin material having photosensitivity, such as an acrylic resin, a polyimide resin or a novolac resin. The reflective electrode 5 can be made from silver or aluminum having a high reflectance.

As will be described later, the ultraviolet-absorbing layer 6 can be made from any material as long as (a) ultraviolet having a wavelength of 365 nm, which is necessary for polymerization for preparing a liquid crystal layer, can pass through the material and (b) ultraviolet (especially ultraviolet having a wavelength of 315 nm, which is emitted from a fluorescent lamp) having a wavelength of not more than 340 nm, which deteriorates a liquid crystal material is absorbed by the material. Examples of the material are a photosensitive acrylic resin, a photosensitive epoxy resin, and like resins.

The transparent electrode 7 can be made from a publicly-known material used for a transparent electrode, such as indium tin oxide (ITO) or indium zinc oxide (IZO).

The ultraviolet-absorbing layer was made from an epoxy resin and had a thickness of 0.5 μm to 6.0 μm. Table shows (i) a transmittance of ultraviolet having a wavelength of 400 nm, 365 nm or 315 nm through the ultraviolet-absorbing layer (ii) a testing result obtained by exposing a reflective LCD device employing the ultra-absorbing layer to light of a fluorescent lamp, and (iii) a hue of white display of the reflective LCD device, the hue being visually evaluated. Specifically, the reflective LCD device was exposed to the light of the fluorescent lamp indoors for 100 hours. In a case where the reflective LCD device had a reflectance reduced by not less than 10%, the reflective LCD device was evaluated as NG. Further, as to the hue, a hue of a produced reflective LCD device was evaluated in terms of how much white display was distant from a white color in a case where the white display was visually evaluated.

TABLE 11

| Thickness of ultraviolet- | | | | | |
|---|---|---|---|---|---|
| absorbing layer (μm) | 0.5 | 1.0 | 1.5 | 3.0 | 6.0 |
| Transmittance at 400 nm (%) | 89.0 | 88.0 | 86.0 | 82.0 | 74.0 |
| Transmittance at 365 nm (%) | 80.0 | 75.0 | 70.0 | 57.0 | 38.0 |
| Transmittance at 315 nm (%) | 24.0 | 12.0 | 6.0 | 1.0 | 0.1 |
| Transmittance ratio (T (365 nm)/ | 3.3 | 6.3 | 11.7 | 57.0 | 380.0 |
| T (315 nm)) | | | | | |
| Testing result obtained by exposing | NG | OK | OK | OK | OK |
| to light of a fluorescent lamp | | | | | |
| Hue | OK | OK | OK | OK | NG |

As is clear from Table 1, the ultraviolet-absorbing layer having a thickness of 0.5 μm did not sufficiently absorb ultraviolet having a wavelength of 315 nm, and had a small transmittance ratio (T (365 nm)/T (315 nm)) of 3.3 where a transmittance at a wavelength of 365 nm is (T (365 nm)) and a transmittance at a wavelength of 315 nm is (T (315 nm)). The ultraviolet-absorbing layer having such a small transmittance ratio caused deterioration in a liquid crystal material and reduction in reflectance of the reflective LCD device, as is clear from the testing result of Table 1.

Meanwhile, the ultraviolet-absorbing layer having a transmittance ratio of not less than 6.3, that is, having a thickness of not less than 1.0 μm efficiently absorbed the ultraviolet having a wavelength of 315 nm. Accordingly, the reflectance of the reflective LCD device was not reduced.

As is clear from Table 1, in a case where the ultraviolet-absorbing layer had a thickness of 6.0 the transmittance at a wavelength of 400 nm was reduced, and a yellowish white was displayed due to reduction in a blue component of light. Accordingly, the ultraviolet-absorbing layer having a thickness of 1.0 μm to 3.0 μm attains not only an excellent testing result obtained by exposure to the light of the fluorescent lamp but also an excellent hue.

The sealing resin 8 may be made from a conventionally well-known UV curable material or thermally curable material, or a mixture thereof.

The liquid crystal layer is produced by injecting between substrates a mixture of a low molecular liquid crystal composition and an unpolymerized prepolymer that are subject to phase dissolution, and then polymerizing the prepolymer. For example, a cured material (UV cured liquid crystal) produced by irradiating a mixture of a UV curable prepolymer and a liquid crystal composition with active beams such as ultraviolet so as to optically cure the mixture can be used as the liquid crystal layer. Using the UV cured liquid crystal as a polymer dispersion liquid crystal makes it possible to polymerize a liquid crystal at short times. Further, the liquid crystal material can be injected by vacuum injection or drop injection.

After the injection of the liquid crystal material, the prepolymer is polymerized by irradiation of ultraviolet. In order to efficiently polymerize the prepolymer, an intensity of ultraviolet having a wavelength of 365 nm is significant.

FIG. 2 illustrates a relationship between an intensity of ultraviolet having a wavelength of 365 nm necessary for polymerization of a polymer and a reflectance of a produced reflective LCD device. The ultraviolet was emitted from a wavelength of not more than 340 nm was eliminated as much as possible by use of a cold filter. The intensity of, the ultraviolet was measured by use of a UV intensity meter UV-M10 (commodity name) and a photoreceiver UV-35 (commodity name) manufactured by ORC MANUFACTURING CO., LTD. The reflectance was measured by a CM2002 (commodity name) manufactured by Konica. Minolta Holdings, Inc. As is clear from FIG. 2, not less than 30 mW/cm² of ultraviolet having a wavelength of 365 nm is required for obtaining a reflectance of not less than 50%. Ultraviolet having a low intensity does not sufficiently produce radicals necessary for polymerizing the polymer. This slows the polymerization of the polymer thereby promoting growth of liquid crystal drops. As a result, the reflectance of the reflective LCD device is reduced.

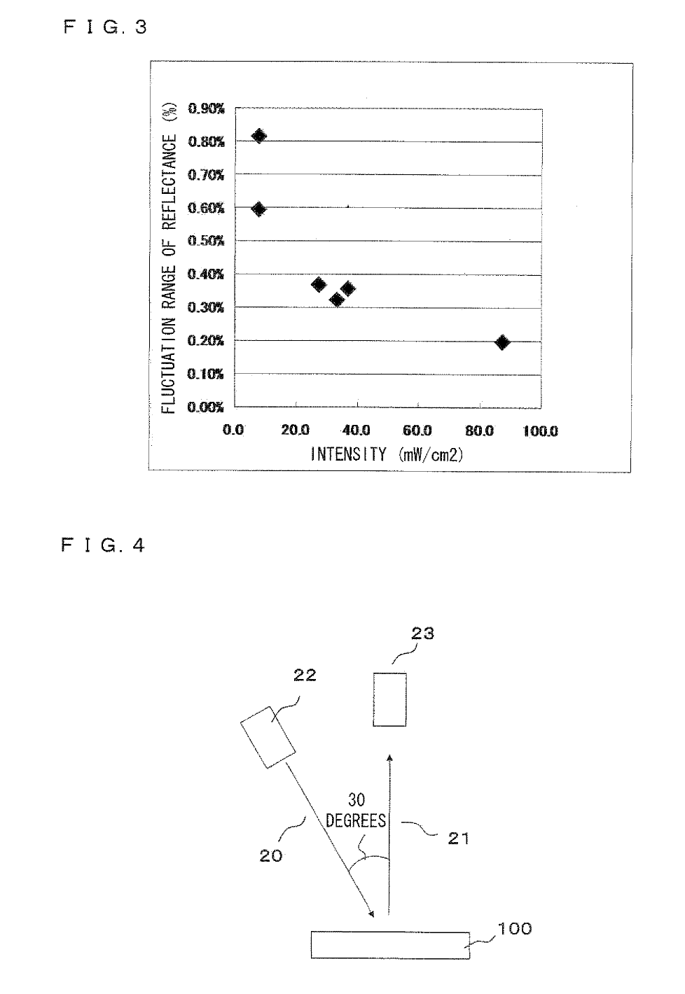

FIG. 3 illustrates a relationship between an intensity of ultraviolet having a wavelength of 365 nm necessary for the polymerization of the polymer and a fluctuation range of a reflectance of a produced reflective LCD device in a case where the produced reflective LCD device displays black. The fluctuation range of the reflectance was measured as shown in FIG. 4. Specifically, a light source 32 positioned at an angle of 30° from a normal line of the reflective LCD device 100 emitted parallel light 30, and an intensity of reflected light 21 reflected in a direction of the normal line, which reflected light 21 was included in the emitted parallel light 30, was measured by a photoreceiver 33. A reference white plate of barium sulfate was used as a reference. Further, a measurement diameter was 2 mmφ.

Whether to cause flickers was visually evaluated. In a case where the fluctuation range of the reflectance was beyond 0.4%, flickers were observed. In order to prevent flickers, not less than 30 mW/cm² of ultraviolet having a wavelength of 365 nm was required.

TABLE 2

| | Condition | Condition | Condition | Condition | Condition | Condition | Condition | Condition |
|---|---|---|---|---|---|---|---|---|
| | 1 | 2 | 3 | 4 | 5 | 6 | 7 | 8 |
| Intensity at 360 nm | 2038.0 | 2250.0 | 2250.0 | 822.0 | 387.0 | 473.0 | 1251.0 | 1251.0 |
| (μW/cm²/nm) | | | | | | | | |
| Intensity at 340 nm | 212.0 | 86.0 | 86.0 | 28.0 | 9.0 | 7.0 | 5.0 | 5.0 |
| (μW/cm²/nm) | | | | | | | | |
| Intensity ratio | 9.6 | 26.2 | 26.2 | 29.4 | 43.0 | 67.6 | 250.2 | 250.2 |
| (I(360 nm)/I(340 nm)) | | | | | | | | |
| Whether to cause | No | No | No | No | Yes | Yes | Yes | Yes |
| deterioration | | | | | | | | |
| in PNLC | | | | | | | | |

Table 2 shows a relationship between (i) an intensity ratio of an intensity of ultraviolet having a wavelength of 365 nm necessary for the polymerization of the polymer to an intensity of ultraviolet having a wavelength of 340 nm and (ii) deterioration in a liquid crystal material. The intensities were measured by a Spectro-Radiometer UV Intensity Meter USR-40 (commodity name) manufactured by USHIO INC. In a case where the intensity ratio is small, a lot of ultraviolet having a wavelength of not more than 340 nm is emitted to the polymer during the polymerization. This leads to the deterioration in the liquid crystal material. As is clear from Table 2, in a case where the intensity ratio is not less than 41, the deterioration in the liquid crystal is prevented.

### Examples

The following describes in detail the present invention on the basis of Examples.

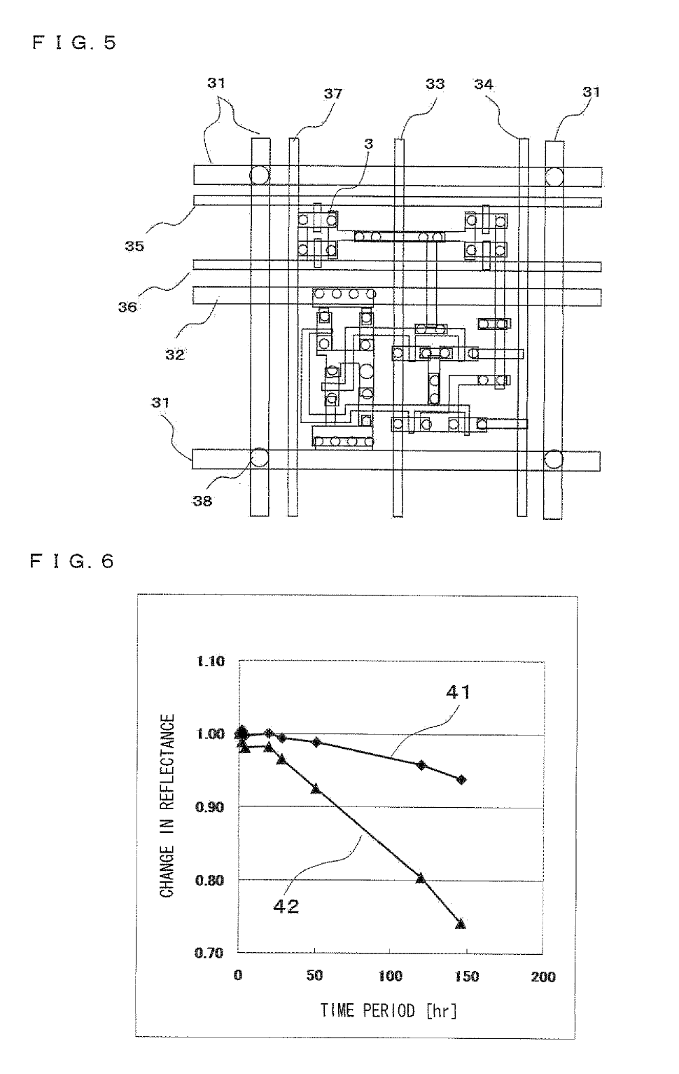

A glass substrate having a thickness of 0.7 mm was used for a first insulating substrate. FIG. 5 illustrates a plain view of a pixel circuit used in the present example. VLAs (pixel voltage supply lines having a phase identical to that of a common electrode) 31 formed parallel to a longitudinal direction or a lateral direction of the pixel circuit surround a region. The region corresponds to a subpixel. The subpixel includes twelve TFT elements 3 constituting two static RAMs. The TFT elements 3 and wirings are provided over the subpixel of the present example. A Vdd 33 and a Vss 34 are wirings for supplying a voltage to the static RAMs. A GL 35 and a GLS 36 are wirings for a ground electric potential. An SL 37 is a wiring for supplying an image signal. A reflective electrode is electrically connected to the VLAs 31 or a VLB (pixel voltage supply line having a phase opposite to that of the common electrode) 32 in response to the image signal supplied from the SL 37. In a case where the reflective electrode is electrically connected to the VLAs 31, an electric potential of the reflective electrode is 0 V. Meanwhile, in a case where the reflective electrode is electrically connected to the VLB 32, the electric potential of the reflective electrode is 5 V. The electrodes of the TFT elements 3 are connected correspondingly to the wirings via respective connection through holes 38 if necessary.

After formation of the TFT elements on the glass substrate, an acrylic interlayer insulating film having a thickness of 2.5 μm was formed on the TFT elements, and Al having a thickness of 100 nm was further formed as the reflective electrode on the acrylic interlayer insulating film. Thereafter, a parallel alignment film was applied to the Al electrode for fabrication of the reflective LCD device. In this manner, the first insulating substrate was produced.

Further, a glass substrate having a thickness of 0.7 mm was also used for a second insulating substrate in the same manner as the first insulating substrate. An epoxy resin was applied to the glass substrate by use of a slit coater. Thereafter, the applied epoxy resin was baked at a temperature of not less than 200° C. so as to have formed an ultraviolet-absorbing layer thereon. An ITO electrode was then formed as a transparent electrode on the ultraviolet-absorbing layer. Thereafter, a parallel alignment film was formed on the ITO electrode in the same manner as the first insulating substrate.

A UV curable sealing material for liquid crystal manufactured by SEKISUI CHEMICAL CO., LTD. was applied as an ultraviolet curable resin to a seal section of the first insulating substrate by use of a dispenser. Thereafter, PNM-170 (commodity name) manufactured by DIC Corporation was injected as a PNLC material into a region surrounded by the sealing material and the first insulating substrate by means of a dropping technique. The second insulating substrate was then attached to the first insulating substrate via the sealing material. Further, spacers were provided between the first and second insulating substrates such that the liquid crystal layer has a thickness of 3 μm.

Ultraviolet from which ultraviolet having a wavelength of not more than 340 nm was eliminated as much as possible by use of a cold filter was emitted from a UV irradiation device, so that the polymerization of the polymer and curing of the sealing material were simultaneously carried out. Specifically, a UV irradiation device using a D bulb manufactured by Fusion UV Systems Japan K.K. was used as the UV irradiation device of the present example under a condition where the ultraviolet had an intensity of 30 mW/cm², and was emitted for 100 seconds. To be sure, the polymerization of the polymer and the curing of the sealing material can be separately carried out. Thereafter, a heat treatment was carried out. The heat treatment makes it possible to thoroughly cure the sealing material and to enhance adhesiveness and reliability of the sealing material. A temperature at the heat treatment is carried out differs from a material to a material. Meanwhile, the temperature preferably ranges from 120° C. to 180° C. Further, a time period for which the heat treatment is carried out preferably ranges from 10 minutes to 120 minutes.

In this manner, the reflective LCD device of the present example is produced.

### Comparative Example

As a comparative example, a reflective LCD device was produced in the same manner as the reflective LCD device of the present example except that the reflective LCD device of the comparative example included no ultraviolet-absorbing layer.

(Evaluation)

These reflective LCD devices were exposed to light emitted from a fluorescent lamp indoors, then a change in reflectance of these reflective LCD devices was observed. FIG. 6 shows a result of the change in reflectance. In FIG. 6, a curve 41 shows a case where the reflective LCD device includes the ultraviolet-absorbing layer, and a curve 42 shows a case where the reflective LCD device does not include the ultraviolet-absorbing layer. The reflective LCD device including the ultraviolet-absorbing layer showed a reflectance that changed by not more than 10% even in a case where the reflective LCD device including the ultraviolet-absorbing layer was exposed to the light emitted from the fluorescent lamp for 150 hours. Meanwhile, the reflective LCD device including no ultraviolet-absorbing layer showed a reflectance reduced by not less than 25%. As is clear from FIG. 6, ultraviolet having a wavelength of 315 nm and ultraviolet having a wavelength of 335 nm emitted from the fluorescent lamp were absorbed into the ultraviolet-absorbing layer. This prevented the liquid crystal material from deteriorating.

According to a method for producing the reflective LCD device of the present invention, it is possible to simultaneously cure the sealing material by irradiation of ultraviolet, and then carry out the heat treatment at 130° C. for 1 hour.

Further, according to the method of the present invention, it is possible to reduce the number of steps for producing the reflective LCD device, and to produce a reflective LCD device having an excellent display quality at low cost because of sufficiently polymerizing the polymer and fully preventing deterioration in liquid crystal due to ultraviolet.

### INDUSTRIAL APPLICABILITY

The present invention is applicable to a reflective LCD device and a method for producing the reflective LCD device.

### REFERENCE SIGNS LIST

100: reflective LCD device
1: first insulating substrate
2: second insulating substrate
3: TFT element
4: interlayer insulating film
5: reflective electrode
6: ultraviolet-absorbing layer
7: transparent electrode
8: sealing resin
9: polymer film
10: liquid crystal drops
20: parallel light
21: reflected light
22: light source
23: photoreceiver
31: VLA
32: VLB
33: Vdd
34: Vss
35: GL
36: GLB
37: SL
38: connection through hole
41: curve showing a change in reflectance in a case where a reflective LCD device includes an ultraviolet-absorbing layer
42: curve showing a change in reflectance in a case where a reflective LCD device includes no ultraviolet-absorbing layer

1. A liquid crystal display device, comprising:
substrates wherein electrodes formed on one of the substrates are paired with electrodes formed on the other one of the substrates;
a liquid crystal sandwiched between the substrates, the liquid crystal being arranged by dispersing liquid crystal drops in a polymer film or by forming a polymer network in a liquid crystal layer; and
an ultraviolet-absorbing layer provided between at least one of the substrates and the pair of electrodes, the ultraviolet-absorbing layer having a transmittance ratio (T (365 nm)/T (315 nm)) of not less than 6.3 where a transmittance at a wavelength of 365 nm is (T (365 nm)) and a transmittance at a wavelength of 315 nm is (T (315 nm)).

2. The liquid crystal display device as set forth in claim 1, monochromically displays.

3. The liquid crystal display device as set forth in claim 1 wherein the ultraviolet-absorbing layer has a thickness of 1.0 μm to 3.0 μm.

4. A reflective liquid crystal display device, comprising:
a first insulating substrate on which (i) a memory including a plurality of active elements, (ii) an interlayer insulating film and (iii) a reflective electrode are formed in this order;
a second insulating substrate on which a transparent electrode is formed, the first insulating substrate and the second insulating substrate being attached to each other such that the reflective electrode formed on the first insulating substrate faces the transparent electrode formed on the second insulating substrate;
a liquid crystal sandwiched between the first insulating substrate and the second insulating substrate, the liquid crystal being arranged by dispersing liquid crystal drops in a polymer film or by forming a polymer network in a liquid crystal layer; and
an ultraviolet-absorbing layer provided between the second insulating substrate and the transparent electrode, the ultraviolet-absorbing layer having a transmittance ratio (T (365 nm)/T (315 nm)) of not less than 6.3 where (T (365 nm)) is a transmittance at a wavelength of 365 nm and T (315 nm) is a transmittance at a wavelength of 315 nm.

5. The reflective liquid crystal display device as set forth in claim 4, monochromically displays.

6. The reflective liquid crystal display device as set forth in claim 4 wherein the ultraviolet-absorbing layer has a thickness of 1.0 μm to 3.0 μm.

7. A method for producing a reflective liquid crystal display device comprising the steps of:
preparing a first insulating substrate on which (i) a memory including a plurality of active elements, (ii) an interlayer insulating film and (iii) a reflective electrode are formed in this order;
preparing a second insulating substrate on which an ultraviolet-absorbing layer and a transparent electrode are formed in this order, the ultraviolet-absorbing layer having a transmittance ratio (T (365 nm)/T (315 nm)) of not less than 6.3 where (T (365 nm)) is a transmittance at a wavelength of 365 nm and (T (315 nm)) is a transmittance at a wavelength of 315 nm;
attaching the first insulating substrate and the second substrate to each other such that the reflective electrode formed on the first insulating substrate faces the transparent electrode formed on the second insulating substrate;
providing a liquid crystal, a monomer and a photopolymerization initiator between the first insulating substrate and the second insulating substrate; and
polymerizing the monomer by irradiating the reflective liquid crystal display device from the second insulating substrate with ultraviolet,
the ultraviolet having an intensity of not less than 30 mW/cm² at a wavelength of 365 nm at a liquid crystal panel surface.

8. The method for producing the reflective liquid crystal display device as set forth in claim 7, wherein
the ultraviolet has an intensity ratio (I (365 nm)/I (340 nm)) of not less than 41 where (I (365 nm)) is an intensity at a wavelength of 365 nm and (I (340 nm)) is an intensity at a wavelength of 340 nm.

9. The method for producing the reflective liquid crystal display device as set forth in claim 7 wherein
the irradiation of the ultraviolet simultaneously cures a sealing material, and a heat treatment is then carried out.

10. The method for producing the reflective liquid crystal display device as set forth in claim 9 wherein
the heat treatment is carried out at a temperature of 120° C. to 180 C.°.

11. The method for producing the reflective liquid crystal display device as set forth in claim 9 wherein
the heat treatment is carried out for 10 minutes to 120 minutes.
